(19) United States
(12) Patent Application Publication
(10) Pub. No.: US 2023/0386791 A1
(43) Pub. Date: Nov. 30, 2023

(54) PLASMA PROCESSING APPARATUS

(71) Applicant: Tokyo Electron Limited, Minato-ku, Tokyo (JP)

(72) Inventors: Taro IKEDA, Nirasaki City, Yamanashi (JP); Satoru KAWAKAMI, Nirasaki City, Yamanashi (JP)

(21) Appl. No.: 18/249,552

(22) PCT Filed: Oct. 15, 2021
(86) PCT No.: PCT/JP2021/038301

§ 371 Date: Apr. 19, 2023

(30) Foreign Application Priority Data
Oct. 29, 2020 (JP) 2020-181449

(51) Int. Cl. H01J 37/32; C23C 16/511; C23C 16/44

(52) U.S. Cl. CPC H01J 37/32229; H01J 37/32311; H01J 37/3244; H01J 37/32357; C23C 16/511; C23C 16/4405; H01J 2237/332

(57) ABSTRACT

Disclosed is a plasma processing apparatus including a chamber and a waveguide structure. The waveguide structure is configured to propagate electromagnetic waves, which are VHF waves or UHF waves, in order to generate plasma within the chamber. The waveguide structure includes a resonator for electromagnetic waves. The resonator includes a first waveguide, a second waveguide, and a load impedance portion. The first waveguide has a first characteristic impedance. The second waveguide has a second characteristic impedance. The second waveguide is terminated at a short-circuit end having a ground potential. The load impedance portion is connected between the first waveguide and the second waveguide. The second characteristic impedance is greater than the first characteristic impedance.

### TECHNICAL FIELD

Exemplary embodiments of the present disclosure relate to a plasma processing apparatus.

### BACKGROUND

A plasma processing apparatus has been used in the manufacture of devices. Japanese patent laid-open publication No. 2011-243635 (hereinafter referred to as “Patent Document 1”) discloses a parallel plate type plasma processing apparatus as a type of plasma processing apparatus.

The plasma processing apparatus disclosed in Patent Document 1 includes a chamber and an upper electrode. The upper electrode constitutes a shower head. The shower head introduces a film formation gas into the chamber. The upper electrode is connected to a radio-frequency power supply. The radio-frequency power supply supplies radio-frequency power to the upper electrode. The radio-frequency power supplied to the upper electrode generates a radio-frequency electric field within the chamber. The generated radio-frequency electric field excites the film formation gas within the chamber to generate plasma. In a film formation processing performed on a substrate, chemical species from the plasma are deposited on the substrate to form a film on the substrate.

Further, the plasma processing apparatus disclosed in Patent Document 1 has a function of cleaning the chamber. Specifically, the plasma processing apparatus disclosed in Patent Document 1 is configured to introduce chemical species such as radicals from remote plasma of a cleaning gas into the chamber from a sidewall of the chamber.

### PRIOR ART DOCUMENT

### Patent Document

Patent Document 1: Japanese Laid-Open Patent Publication No. 2011-243635

The present disclosure provides a technique for shortening a length of a resonator in a waveguide of electromagnetic waves in a plasma processing apparatus that generates plasma within a chamber using the electromagnetic waves.

### SUMMARY

In one exemplary embodiment, a plasma processing apparatus is provided. The plasma processing apparatus includes a chamber and a waveguide structure. The waveguide structure is configured to propagate electromagnetic waves, which are VHF waves or UHF waves, in order to generate plasma within the chamber. The waveguide structure includes a resonator that resonates the electromagnetic waves inside the waveguide structure. The resonator includes a first waveguide, a second waveguide, and a load impedance portion. The first waveguide has a first characteristic impedance. The second waveguide has a second characteristic impedance. The second waveguide is terminated at a short-circuit end having a ground potential. The load impedance portion is connected between the first waveguide and the second waveguide. The second characteristic impedance is greater than the first characteristic impedance.

According to one exemplary embodiment, it is possible to shorten a length of a resonator in a waveguide structure of electromagnetic waves in a plasma processing apparatus that generates plasma within a chamber using the electromagnetic waves.

### BRIEF DESCRIPTION OF DRAWINGS

FIG. 1 is a cross-sectional view schematically illustrating a plasma processing apparatus according to one exemplary embodiment.

FIG. 2 is a partially enlarged cross-sectional view of the plasma processing apparatus according to one exemplary embodiment.

FIG. 3 is a cross-sectional view taken along line III-III in FIG. 2.

FIG. 4 is a cross-sectional view taken along line IV-IV in FIG. 2.

### DETAILED DESCRIPTION

Hereinafter, various exemplary embodiments will be described.

In one exemplary embodiment, a plasma processing apparatus is provided. The plasma processing apparatus includes a chamber and a waveguide structure. The waveguide structure is configured to propagate an electromagnetic wave that is a VHF wave or a UHF wave to generate plasma within the chamber. The waveguide structure includes a resonator configured to resonate the electromagnetic wave therein. The resonator includes a first waveguide, a second waveguide, and a load impedance portion. The first waveguide has a first characteristic impedance. The second waveguide has a second characteristic impedance. The second waveguide is terminated at a short-circuit end having a ground potential. The load impedance portion is connected between the first waveguide and the second waveguide. The second characteristic impedance is greater than the first characteristic impedance.

In the above embodiment, since the second characteristic impedance is greater than the first characteristic impedance, a resonance condition in the resonator is satisfied even if the length of the second waveguide is short. Thus, it is possible to shorten a length of the resonator in the waveguide structure of electromagnetic waves in the plasma processing apparatus that generates plasma within the chamber using the electromagnetic waves.

In one exemplary embodiment, a length of the first waveguide and a length of the second waveguide may be substantially the same.

In one exemplary embodiment, the length of the second waveguide that is the length of the resonator may be less than ⅛ of an effective wavelength of the electromagnetic wave within the resonator.

In one exemplary embodiment, the first waveguide may be provided by a first coaxial tube including an inner conductor and an outer conductor. The load impedance portion may extend continuously from the first waveguide along a direction in which the first coaxial tube extends. The second waveguide may be provided by a second coaxial tube including an inner conductor that is the outer conductor of the first coaxial tube and an outer conductor, and may extend so as to surround the first waveguide and the load impedance portion. In the resonator, the second waveguide may be folded with respect to a portion composed of the first waveguide and the load impedance portion.

In one exemplary embodiment, the plasma processing apparatus may further include a dielectric part. The dielectric part is formed of a dielectric and is arranged between the inner conductor of the first coaxial tube and the outer conductor of the first coaxial tube. The dielectric part may extend along the inner conductor of the first coaxial tube to a potion within the load impedance portion so as to protrude from an end portion of the first waveguide. In this embodiment, since the dielectric part extends from the second waveguide so as to hide the inner conductor of the first coaxial tube, abnormal discharge such as arc discharge or creeping discharge inside the resonator is prevented.

In one exemplary embodiment, the inner conductor of the first coaxial tube may configure a gas supply pipe.

In one exemplary embodiment, the plasma processing apparatus may further include a substrate supporter, a shower head, and an introducer. The substrate supporter is provided inside the chamber. The shower head is formed of a metal and is provided above the substrate supporter. The shower head provides a plurality of gas holes that are open toward a space within the chamber. The introducer is formed of a dielectric and is provided along an outer periphery of the shower head or a sidewall of the chamber so as to introduce the electromagnetic wave into the chamber therefrom. The gas supply pipe extends vertically above the chamber, is connected to a top center of the shower head, and provides a waveguide connected to the resonator between the resonator and the introducer.

In one exemplary embodiment, the plasma processing apparatus may further include an electromagnetic wave supply path. The gas supply pipe may include an annular flange. The supply path may include a conductor connected to the flange. The resonator may be provided above the flange with respect to the chamber.

In one exemplary embodiment, the plasma processing apparatus may further include a first gas source, a second gas source, and a remote plasma source. The first gas source is a gas source for a film formation gas and is connected to the gas supply pipe. The second gas source is a gas source for a cleaning gas. The remote plasma source is connected between the second gas source and the gas supply pipe.

In one exemplary embodiment, the film formation gas may include a silicon-containing gas. In one exemplary embodiment, the cleaning gas may include a halogen-containing gas.

Hereinafter, various exemplary embodiments will be described in detail with reference to the drawings. In addition, the same reference numerals will be given to the same or corresponding parts in each drawing.

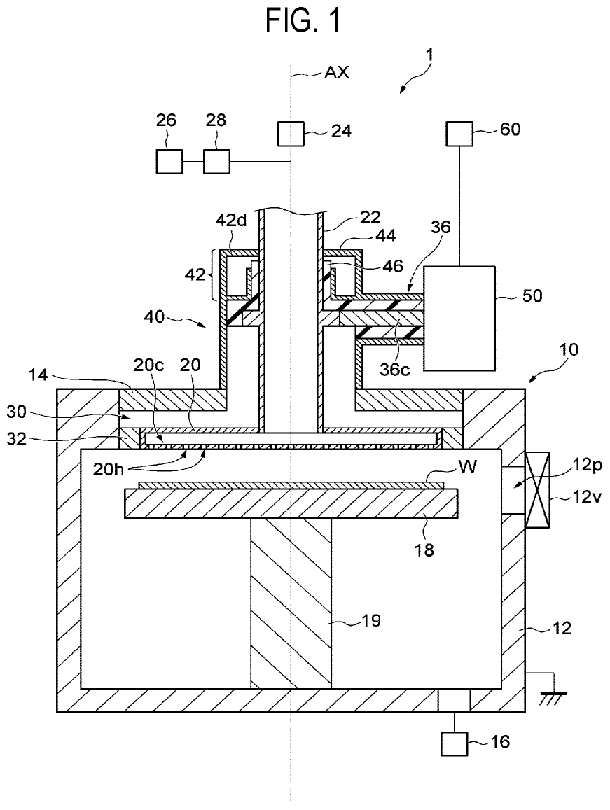

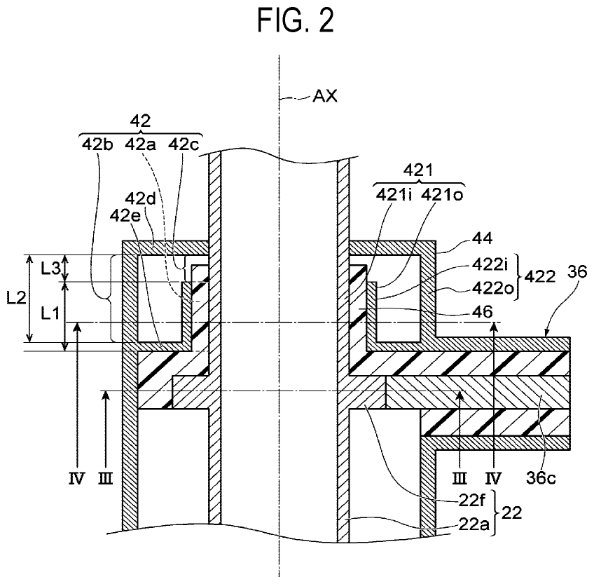

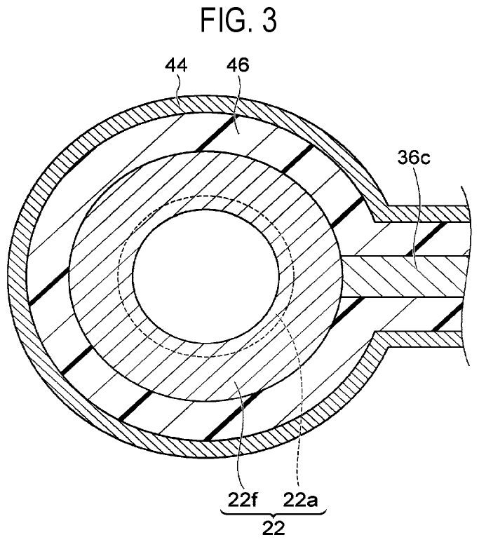

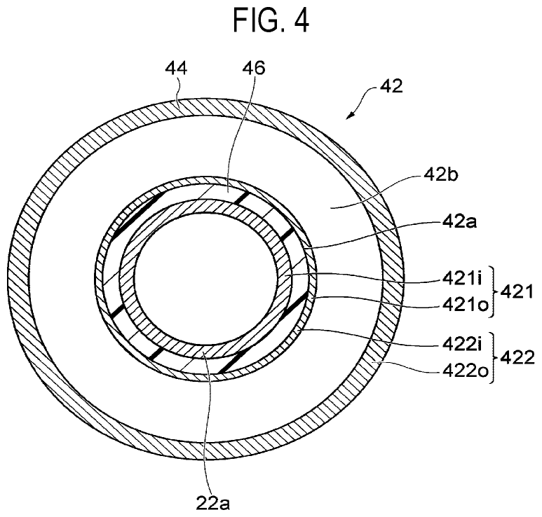

FIG. 1 is a cross-sectional view schematically illustrating a plasma processing apparatus according to one exemplary embodiment. FIG. 2 is a partially enlarged view of the plasma processing apparatus illustrated in FIG. 1. FIG. 3 is a cross-sectional view taken along line III-III in FIG. 2. FIG. 4 is a cross-sectional view taken along line IV-IV in FIG. 2. The plasma processing apparatus 1 illustrated in FIGS. 1 to 4 is configured to generate plasma using electromagnetic waves. The electromagnetic waves are VHF waves or UHF waves. A band of the VHF waves is 30 MHz to 300 MHz, and a band of the UHF waves is 300 MHz to 3 GHz.

The plasma processing apparatus 1 includes a chamber 10. The chamber 10 defines an interior space therein. A substrate W is processed in the interior space of the chamber 10. The chamber 10 has an axis AX as the central axis thereof. The axis AX is an axis extending in the vertical direction.

In one embodiment, the chamber 10 may include a chamber main body 12. The chamber main body 12 has a substantially cylindrical shape and is open at the top thereof. The chamber main body 12 provides a sidewall and bottom of the chamber 10. The chamber main body 12 is formed of a metal such as aluminum. The chamber main body 12 is grounded.

A sidewall of the chamber main body 12 provides a passage 12p. The substrate W passes through the passage 12p when being transferred between the interior and exterior of the chamber 10. The passage 12p may be opened and closed by a gate valve 12v. The gate valve 12v is provided along the sidewall of the chamber main body 12.

The chamber 10 may further include a top wall 14. The top wall 14 is formed of a metal such as aluminum. The top wall 14 closes a top opening of the chamber main body 12 in conjunction with a cover conductor to be described later. The top wall 14 is grounded together with the chamber main body 12.

The bottom of the chamber 10 provides an exhaust port. The exhaust port is connected to an exhaust device 16. The exhaust device 16 includes a pressure controller such as an automatic pressure control valve and a vacuum pump such as a turbo-molecular pump.

The plasma processing apparatus 1 may further include a substrate supporter 18. The substrate supporter 18 is provided inside the chamber 10. The substrate supporter 18 is configured to support the substrate W placed thereon. The substrate W is placed on the substrate supporter 18 in a substantially horizontal posture. The substrate supporter 18 may be supported by a support member 19. The support member 19 extends upwardly from the bottom of the chamber 10. The substrate supporter 18 and the support member 19 may be formed of a dielectric such as aluminum nitride.

The plasma processing apparatus 1 may further include a shower head 20. The shower head 20 is formed of a metal such as aluminum. The shower head 20 has a substantially disk shape and may have a hollow structure. The shower head 20 shares the axis AX as the central axis thereof. The shower head 20 is provided above the substrate supporter 18 and below the top wall 14. The shower head 20 configures a ceiling portion that defines the interior space of the chamber 10.

The shower head 20 provides a plurality of gas holes 20h. The plurality of gas holes are open toward the interior space of the chamber 10. The shower head 20 further provides a gas diffusion chamber 20c therein. The plurality of gas holes 20h are connected to the gas diffusion chamber 20c and extend downward from the gas diffusion chamber 20c.

The plasma processing apparatus 1 may further include a gas supply pipe 22. The gas supply pipe 22 is a cylindrical pipe. The gas supply pipe 22 is formed of a metal such as aluminum. The gas supply pipe 22 extends vertically above the shower head 20. The gas supply pipe 22 shares the axis AX as the central axis thereof. A lower end of the gas supply pipe 22 is connected to the top center of the shower head 20. The top center of the shower head provides a gas inlet. The inlet is connected to the gas diffusion chamber 20c. The gas supply pipe 22 supplies a gas to the shower head 20. The gas from the gas supply pipe 22 is introduced from the plurality of gas holes 20h into the chamber 10 through the inlet and the gas diffusion chamber 20c of the shower head 20.

In one embodiment, the plasma processing apparatus 1 may further include a first gas source 24, a second gas source 26, and a remote plasma source 28. The first gas source 24 is connected to the gas supply pipe 22. The first gas source 24 may be a gas source for a film formation gas. The film formation gas may include a silicon-containing gas. The silicon-containing gas includes, for example, SiH₄. The film formation gas may further include other gases. For example, the film formation gas may further include an NH₃ gas, an N₂ gas, a noble gas such as Ar, and the like. The gas (for example, the film formation gas) from the first gas source 24 is introduced into the chamber 10 from the shower head 20 through the gas supply pipe 22.

The second gas source 26 is connected to the gas supply pipe 22 via the remote plasma source 28. The second gas source 26 may be a gas source for a cleaning gas. The cleaning gas may include a halogen-containing gas. The halogen-containing gas includes, for example, NF₃ and/or Cl₂. The cleaning gas may further include other gases. The cleaning gas may further include a noble gas such as Ar.

The remote plasma source 28 excites the gas from the second gas source 26 to generate plasma at a location spaced apart from the chamber 10. In one embodiment, the remote plasma source 28 generates plasma from the cleaning gas. The remote plasma source 28 may be any type of plasma source. Examples of the remote plasma source 28 include a capacitively coupled plasma source, an inductively coupled plasma source, and a type of plasma source that generates plasma using microwaves. Radicals in the plasma generated in the remote plasma source 28 are introduced into the chamber 10 from the shower head 20 through the gas supply pipe 22. In order to prevent deactivation of the radicals, the gas supply pipe 22 may have a relatively large diameter. An outer diameter (diameter) of the gas supply pipe 22 is, for example, 40 mm or more. In one example, the outer diameter (diameter) of the gas supply pipe 22 is 80 mm. In addition, the gas supply pipe 22 has a cylindrical shape, and the outer diameter (diameter) of the gas supply pipe 22 is the outer diameter of a portion 22a of the gas supply pipe 22 other than a flange 22f. The flange 22f having an annular shape configures a portion of the gas supply pipe 22 in the longitudinal direction. The flange 22f radially protrudes from the other portion 22a of the gas supply pipe 22. This gas supply pipe 22 may configure a portion of a waveguide structure 40 to be described later.

The shower head 20 is spaced apart downward from the top wall 14. A space between the shower head 20 and the top wall 14 configures a portion of a waveguide 30. The waveguide also includes a space provided by the gas supply pipe 22 between the gas supply pipe 22 and the top wall 14.

The plasma processing apparatus 1 may further include an introducer 32. The introducer 32 is formed of a dielectric such as aluminum oxide. The introducer 32 is provided along the outer periphery of the shower head 20 so as to introduce electromagnetic waves into the chamber 10 therefrom. The introducer 32 has an annular shape. The introducer 32 closes a gap between the shower head 20 and the chamber main body 12 and is connected to the waveguide 30. In addition, the introducer 32 may be provided along the sidewall of the chamber 10.

The plasma processing apparatus 1 further includes the waveguide structure 40. The waveguide structure 40 is configured to propagate electromagnetic waves in order to generate plasma within the chamber 10. The waveguide structure 40 may be provided above the chamber 10.

The plasma processing apparatus 1 may further include a supply path 36 for electromagnetic waves. The supply path 36 is connected to the waveguide structure 40. In one embodiment, the supply path 36 includes a conductor 36c. The conductor 36c of the supply path 36 is connected to the gas supply pipe 22. Specifically, one end of the conductor 36c is connected to the flange 22f.

The plasma processing apparatus 1 may further include a matcher 50 and a power supply 60. The other end of the conductor 36c is connected to the power supply 60 via the matcher 50. The power supply 60 is a generator of electromagnetic waves. The matcher 50 includes an impedance matching circuit. The impedance matching circuit is configured to match a load impedance of the power supply 60 to an output impedance of the power supply 60. The impedance matching circuit has a variable impedance. The impedance matching circuit may be, for example, a π-type circuit.

In the plasma processing apparatus 1, the electromagnetic waves from the power supply are introduced into the chamber 10 from the introducer 32 via the matcher 50, the supply path 36 (conductor 36c), the waveguide structure 40, and the waveguide 30 around the shower head 20. The electromagnetic waves excite the gas (for example, the film formation gas) from the first gas source 24 within the chamber 10 to generate plasma.

The waveguide structure 40 includes a resonator 42 that resonates electromagnetic waves therein. In one embodiment, the resonator 42 is provided above the flange 22f The resonator 42 includes a first waveguide 42a, a second waveguide 42b, and a load impedance portion 42c. The first waveguide 42a has a first characteristic impedance Z₁. The second waveguide 42b has a second characteristic impedance Z₂. The second waveguide 42b is terminated at a short-circuit end 42e. The short-circuit end 42e is formed of a metal and has a ground potential. The load impedance portion 42c is a waveguide connected between the first waveguide 42a and the second waveguide 42b.

In one embodiment, the first waveguide 42a is a cylindrical waveguide that extends vertically. A central axis of the first waveguide 42a substantially coincides with the axis AX. In one embodiment, the first waveguide 42a is provided by a first coaxial tube 421. The first coaxial tube 421 includes an inner conductor 421i and an outer conductor 421o. The inner conductor 421i and the outer conductor 421o have a cylindrical shape. Each of the inner conductor 421i and the outer conductor 421o share the axis AX as the central axis thereof. The first waveguide 42a is formed between the inner conductor 421i and the outer conductor 421o. In one embodiment, the inner conductor 421i may be provided by the gas supply pipe 22 (or the portion 22a).

The load impedance portion 42c extends continuously from the first waveguide 42a along a direction in which the first coaxial tube 421 extends. The load impedance portion 42c is connected to the second waveguide 42b.

In one embodiment, the second waveguide 42b is a cylindrical waveguide that extends vertically. A central axis of the second waveguide 42b substantially coincides with the axis AX. The second waveguide 42b extends so as to surround the first waveguide 42a and the load impedance portion 42c. The second waveguide 42b is folded at an end portion 42d with respect to a portion composed of the first waveguide 42a and the load impedance portion 42c. The end portion 42d is formed of a metal and has a ground potential. Further, a lower end of the second waveguide 42b is terminated by the short-circuit end 42e that extends substantially horizontally.

In one embodiment, the second waveguide 42b is provided by a second coaxial tube 422. The second coaxial tube 422 includes an inner conductor 422i and an outer conductor 422o. The inner conductor 422i and the outer conductor 422o have a cylindrical shape. Each of the inner conductor 422i and the outer conductor 422o share the axis AX as the central axis thereof. The second waveguide 42b is formed between the inner conductor 422i and the outer conductor 422o. In one embodiment, the second coaxial tube 422 includes the outer conductor 421o of the first coaxial tube 421 as the inner conductor 422i thereof.

In one embodiment, a length L2 of the second waveguide 42b is substantially equal to the vertical length of the resonator 42. The length L2 of the second waveguide 42b, that is, the vertical length of the resonator 42 may be less than ⅛ of an effective wavelength λg of electromagnetic waves within the resonator 42. Further, in one embodiment, the length L2 of the second waveguide 42b is substantially the same as a length L1 of the first waveguide 42a. Specifically, a difference between the length L2 of the second waveguide 42b and the length L1 of the first waveguide 42a may be equal to or less than 10% of λg/8 and more specifically, may be equal to or less than 5% from the viewpoint of eliminating reflection at the short-circuit end 42e. On the contrary, the difference may be equal to or greater than 2 mm from the viewpoint of preventing atmospheric discharge. Further, a length L3 of the load impedance portion 42c is equal to or less than 10% of λg/8 if a plate thickness of the short-circuit end 42e is ignored, similarly to the difference between the length L2 of the second waveguide 42b and the length L1 of the first waveguide 42a.

In one embodiment, the plasma processing apparatus 1 may further include a cover conductor 44 and a dielectric part 46. The cover conductor 44 has a substantially cylindrical shape. The cover conductor 44 surrounds the gas supply pipe 22 above the chamber 10. The cover conductor 44 is grounded and has a ground potential.

The cover conductor 44 is connected to the gas supply pipe 22 at an upper end thereof. In other words, the upper end of the cover conductor 44 closes a space between the cover conductor 44 and the gas supply pipe 22. The upper end of the cover conductor 44 may extend substantially horizontally, or may provide the end portion 42d of the resonator 42. Further, the cover conductor 44 may provide the outer conductor 422o of the second coaxial tube 422.

The cover conductor 44 may provide the outer conductor 421o of the first coaxial tube 421 and the inner conductor 422i of the second coaxial tube 422. Further, the cover conductor 44 may provide the short-circuit end 42e of the resonator 42. In addition, the outer conductor 421o of the first coaxial tube 421, the inner conductor 422i of the second coaxial tube 422, and the short-circuit end 42e of the resonator 42 may be formed by conductors separate from the cover conductor 44.

A lower end of the cover conductor 44 is connected to the chamber 10. In one embodiment, the lower end of the cover conductor 44 may be connected to the top wall 14. The cover conductor 44 may surround the conductor 36c. Alternatively, a conductor separate from the cover conductor 44 may surround the conductor 36c. A space between the cover conductor 44 and the conductor 36c may be filled with a dielectric part. This dielectric part may be integrated with the dielectric part 46.

The dielectric part 46 is formed of a dielectric. The dielectric part 46 is formed of, for example, polytetrafluoroethylene (PTFE). A position of a lower end of the dielectric part 46 inside the cover conductor 44 is substantially the same as a vertical position of a lower surface of the flange 22f. The dielectric part 46 extends from an outer peripheral surface of the gas supply pipe 22 to an inner peripheral surface of the cover conductor 44 below a lower surface of the short-circuit end 42e. Further, the dielectric part 46 is arranged between the inner conductor 421i and the outer conductor 421o. In other words, a space between the inner conductor 421i and the outer conductor 421o is filled with the dielectric part 46. In one embodiment, the dielectric part 46 extends along the inner conductor 421i to a potion within the load impedance portion 42c so as to protrude from an end portion (upper end) of the first waveguide 42a.

Here, an input impedance Zᵢₙ of the resonator 42 is represented by the following equation (1).

$$\begin{matrix}[ Equation 1 ] & \\ {Z}_{in} = {Z}_{1} \frac{{Z}_{L 1} + {jZ}_{1} tan {θ}_{1}}{{Z}_{1} + {jZ}_{L 1} tan {θ}_{1}} & ( 1 )\end{matrix}$$

In Equation (1) above, Z_{L1} is the load impedance for the first waveguide 42a, that is, the impedance of the load impedance portion 42c, and is represented by the following equation (2).

$$\begin{matrix}[ Equation 1 ] & \\ {Z}_{L 1} = {Z}_{2} \frac{{Z}_{L 2} + {jZ}_{2} tan {θ}_{2}}{{Z}_{2} + {jZ}_{L 2} tan {θ}_{2}} & ( 2 )\end{matrix}$$

In Equation (2) above, Z_{L2} is the load impedance for the second waveguide 42b. In Equations (1) and (2) above, θ₁ and θ₂ are electrical angles represented by the following equations (3) and (4), respectively.

$$\begin{matrix}[ Equation 3 ] & \\ {θ}_{1} = 2 π \frac{L 1}{{λ}_{g}} & ( 3 )\end{matrix}$$

$$\begin{matrix}[ Equation 4 ] & \\ {θ}_{2} = 2 π \frac{L 2}{{λ}_{g}} & ( 4 )\end{matrix}$$

ZL2 is zero since the second waveguide 42b is short-circuited at the short-circuit end 42e. Thus, the following equation (5) is derived from Equation (2) above.

[Equation 5]

Z_{L1}=jZ₂ tan θ₂ (5)

Further, since the length L1 of the first waveguide 42a and the length L2 of the second waveguide 42b are substantially the same, θ₁ and θ₂ are substantially the same. Thus, the following equation (6) is derived from Equations (1) and (5) above.

$$\begin{matrix}[ Equation 6 ] & \\ {Z}_{in} = {Z}_{1} \frac{j ( {Z}_{1} + {Z}_{2} ) tan {θ}_{2}}{{Z}_{1} - {Z}_{2} {tan}^{2} {θ}_{2}} & ( 6 )\end{matrix}$$

Further, the input impedance Zᵢₙ is infinite if the resonance condition is satisfied. Thus, the following equation (7) is derived from Equation (6) above.

[Equation 7]

Z₁−Z₂ tan²θ₂=0 (7)

In the plasma processing apparatus 1, the second characteristic impedance Z₂ is greater than the first characteristic impedance Z₁. Thus, as can be understood from Equations (7) and (4) above, the resonance condition in the resonator 42 is satisfied even if the length L2 of the second waveguide 42b is shortened. Therefore, according to the plasma processing apparatus 1, it is possible to reduce the length of the resonator 42. For example, as described above, the length of the resonator 42 may be less than ⅛ of the effective wavelength λg. The length of the resonator 42 may be approximately 1/16 of the effective wavelength λg.

In one embodiment, as described above, the dielectric part 46 extends along the inner conductor 421i to the potion within the load impedance portion 42c so as to protrude from the end portion (upper end) of the first waveguide 42a. In this case, since the dielectric part 46 extends from the second waveguide 42b so as to hide the inner conductor 421i of the first coaxial tube 421, abnormal discharge such as arc discharge or creeping discharge within the resonator 42 is prevented.

Further, in the plasma processing apparatus 1, the gas supply pipe 22 is connected to the top center of the shower head 20, and the conductor 36c of the electromagnetic wave supply path 36 is connected to the flange 22f of the gas supply pipe 22. Thus, the electromagnetic waves propagate uniformly around the gas supply pipe 22. The electromagnetic waves are introduced into the chamber 10 from the introducer 32 provided along the outer periphery of the shower head 20 via the gas supply pipe 22 and the shower head 20. Therefore, according to the plasma processing apparatus 1, it is possible to enhance the uniformity of plasma density distribution within the chamber 10.

Further, according to the plasma processing apparatus 1, deposits formed inside the chamber 10 by a film formation processing may be removed by radicals from the plasma of the cleaning gas. Since the radicals from the plasma of the cleaning gas are supplied via the gas supply pipe 22 and the shower head 20, deactivation of the radicals is prevented and the radicals are uniformly supplied into the chamber 10. Thus, according to the plasma processing apparatus 1, cleaning of the chamber 10 may be performed uniformly and efficiently. In the plasma processing apparatus that uses VHF waves or UHF waves as electromagnetic waves, it is necessary to supply the electromagnetic waves into the chamber via the center of the shower head in order to keep the plasma density distribution uniform within the chamber. In addition, in order to efficiently and uniformly clean the chamber, it is necessary to introduce cleaning radicals from the remote plasma source into the chamber via a relatively thick gas supply pipe connected to the center of the shower head. However, in a structure of a plasma processing apparatus in the related art, it was difficult to achieve both the uniformity of plasma density distribution and the uniformity of cleaning. This is because it was difficult to realize both the introduction of electromagnetic waves into the chamber via the center of the shower head and the introduction of radicals into the chamber via the gas supply pipe connected to the center of the shower head. On the other hand, according to the plasma processing apparatus 1, it is possible to improve the uniformity of plasma density distribution inside the chamber 10 as well as the uniformity of cleaning inside the chamber 10.

Although various exemplary embodiments have been described above, the present disclosure is not limited to the exemplary embodiments described above, and various omissions, substitutions, and changes may be made. In addition, elements in different embodiments may be combined to form other embodiments.

From the foregoing description, it should be understood that various embodiments of the present disclosure have been described herein for purposes of illustration, and that various modifications can be made without departing from the scope and spirit of the present disclosure. Accordingly, the various embodiments disclosed herein are not intended to be limiting, and the true scope and spirit of the present disclosure are indicated by the appended claims.

### EXPLANATION OF REFERENCE NUMERALS

1: plasma processing apparatus, 10: chamber, 40: waveguide structure, 42: resonator, 42a: first waveguide, 42b: second waveguide, 42c: load impedance portion

1. A plasma processing apparatus comprising:
a chamber; and
a waveguide structure configured to propagate an electromagnetic wave that is a VHF wave or a UHF wave to generate plasma within the chamber, and including a resonator configured to resonate the electromagnetic wave inside the waveguide structure,
wherein the resonator includes:
a first waveguide having a first characteristic impedance;
a second waveguide having a second characteristic impedance and terminated at a short-circuit end having a ground potential; and
a load impedance portion connected between the first waveguide and the second waveguide, and
wherein the second characteristic impedance is greater than the first characteristic impedance.

2. The plasma processing apparatus of claim 1, wherein a length of the first waveguide and a length of the second waveguide are substantially the same.

3. The plasma processing apparatus of claim 2, wherein the length of the second waveguide, which corresponds to a length of the resonator, is less than ⅛ of an effective wavelength of the electromagnetic wave within the resonator.

4. The plasma processing apparatus of claim 3, wherein the first waveguide is provided by a first coaxial tube including an inner conductor and an outer conductor,
wherein the load impedance portion extends continuously from the first waveguide along a direction in which the first coaxial tube extends,
wherein the second waveguide is provided by a second coaxial tube including an inner conductor as the outer conductor of the first coaxial tube and an outer conductor, the second waveguide extending so as to surround the first waveguide and the load impedance portion, and
wherein, in the resonator, the second waveguide is folded with respect to a portion composed of the first waveguide and the load impedance portion.

5. The plasma processing apparatus of claim 4, further comprising: a dielectric part formed of a dielectric material and arranged between the inner conductor of the first coaxial tube and the outer conductor of the first coaxial tube,
wherein the dielectric part extends along the inner conductor of the first coaxial tube to a potion within the load impedance portion so as to protrude from an end portion of the first waveguide.

6. The plasma processing apparatus of claim 5, wherein the inner conductor of the first coaxial tube configures a gas supply pipe.

7. The plasma processing apparatus of claim 6, further comprising:
a substrate supporter provided inside the chamber;
a shower head formed of a metal, provided above the substrate supporter and including a plurality of gas holes formed to be open toward a space within the chamber; and
an introducer formed of a dielectric and provided along an outer periphery of the shower head or a sidewall of the chamber so as to introduce the electromagnetic wave into the chamber from the introducer,
wherein the gas supply pipe extends vertically above the chamber, is connected to a top center of the shower head, and provides a waveguide connected to the resonator between the resonator and the introducer.

8. The plasma processing apparatus of claim 7, further comprising:
a supply path through which the electromagnetic wave is supplied,
wherein the gas supply pipe includes an annular flange,
wherein the supply path includes a conductor connected to the annular flange, and
wherein the resonator is provided above the flange with respect to the chamber.

9. The plasma processing apparatus of claim 8, further comprising:
a first gas source for a film formation gas connected to the gas supply pipe;
a second gas source for a cleaning gas; and
a remote plasma source connected between the second gas source and the gas supply pipe.

10. The plasma processing apparatus of claim 9, wherein the film formation gas includes a silicon-containing gas.

11. The plasma processing apparatus of claim 10, wherein the cleaning gas includes a halogen-containing gas.

12. The plasma processing apparatus of claim 1, wherein the first waveguide is provided by a first coaxial tube including an inner conductor and an outer conductor,
wherein the load impedance portion extends continuously from the first waveguide along a direction in which the first coaxial tube extends,
wherein the second waveguide is provided by a second coaxial tube including an inner conductor as the outer conductor of the first coaxial tube and an outer conductor, the second waveguide extending so as to surround the first waveguide and the load impedance portion, and
wherein, in the resonator, the second waveguide is folded with respect to a portion composed of the first waveguide and the load impedance portion.

13. The plasma processing apparatus of claim 4, wherein the inner conductor of the first coaxial tube configures a gas supply pipe.

14. The plasma processing apparatus of claim 6, further comprising: a supply path through which the electromagnetic wave is supplied,
wherein the gas supply pipe includes an annular flange,
wherein the supply path includes a conductor connected to the annular flange, and
wherein the resonator is provided above the flange with respect to the chamber.

15. The plasma processing apparatus of claim 6, further comprising:
a first gas source for a film formation gas connected to the gas supply pipe;
a second gas source for a cleaning gas; and
a remote plasma source connected between the second gas source and the gas supply pipe.

16. The plasma processing apparatus of claim 9, wherein the cleaning gas includes a halogen-containing gas.
